(19) United States
(12) Patent Application Publication
(10) Pub. No.: US 2019/0101829 A1
(43) Pub. Date: Apr. 4, 2019

(54) PHOTORESIST PATTERNING ON SILICON NITRIDE

(71) Applicant: International Business Machines Corporation, Armonk, NY (US)

(72) Inventors: Indira P. Seshadri, Niskayuna, NY (US); Ekmini Anuja De Silva, Slingerlands, NY (US); Chi-Chun Liu, Altamont, NY (US); Cheng Chi, Jersey City, NJ (US); Jing Guo, Niskayuna, NY (US); Luciana Meli Thompson, Albany, NY (US)

(21) Appl. No.: 15/719,608

(22) Filed: Sep. 29, 2017

(51) Int. Cl. G03F 7/11; G03F 7/16

(52) U.S. Cl. CPC G03F 7/11; G03F 7/162

(57) ABSTRACT

Embodiments of the present invention provide systems and methods for trapping amines. This in turn mitigates the undesired scumming and footing effects in a photoresist. The polymer brush is grafted onto a silicon nitride surface. The functional groups and molecular weight of the polymer brush provide protons and impose steric hindrance, respectively, to trap amines diffusing from a silicon nitride surface.

### BACKGROUND

The present invention relates generally to the field of materials science, and more particularly to photoresist patterning.

Extreme ultraviolet (EUV) lithography is an emerging lithography technology that uses high-energy ultraviolet radiation. EUV is used in photoelectron spectroscopy, solar imaging, and lithography. The EUV radiation spans from 10 nanometers (nm) to 124 nm, which corresponds to photons having energies from 124 electron volts (eV) down to 10 eV, respectively. Extreme ultraviolet lithography (EUVL) departs from more standard deep ultraviolet lithography (DUVL). In contrast to deep ultraviolet radiation, all matter absorbs EUV radiation and thus, EUVL requires a vacuum. A EUVL tool includes: a laser-driven tin (Sn) plasma light source and reflective optics comprising multilayer mirrors under a hydrogen atmosphere. The hydrogen atmosphere is used to keep the EUV collector mirror in the Sn plasma light source free of Sn deposition.

### SUMMARY

According to one embodiment of the present invention, a method is provided. The method comprises: dissolving a plurality of polymer brushes in a casting solvent, wherein the plurality of polymer brushes contain a first constituent unit and a second constituent unit; dissolving a plurality of photoresists in the casting solvent; wetting the plurality of photoresists; and grafting the plurality of polymer brushes to a silicon nitride surface.

Another embodiment of the present invention provides a photoresist system containing a plurality of polymer brush deriving from a single constituent unit polymer, based on the method described above.

Another embodiment of the present invention provides a photoresist system containing a polymer brush deriving from a two constituent unit polymer, based on the method described above.

### BRIEF DESCRIPTION OF THE SEVERAL VIEWS OF THE DRAWINGS

FIG. 1 is a diagram illustrating an etching environment, in accordance with an embodiment of the present invention;

FIG. 2 is a diagram illustrating amine trapping by the polymer brush, in accordance with an embodiment of the present invention;

FIG. 3 is a diagram illustrating the polymers used to derive the polymer brushes that traps amine, in accordance with an embodiment of the present invention;

FIG. 4 is a diagram comparing scanning electron microscope images where the polymer brush is applied and the polymer brush is not applied, in accordance with an embodiment of the present invention; and

FIG. 5 is a flowchart describing the formation of a polymer brush grafted system, in accordance with an embodiment of the present invention.

### DETAILED DESCRIPTION

During the manufacturing of integrated circuit, silicon nitride (Si₃N₄) is often used as: (i) an insulator and chemical barrier to electrically isolate different structures; or (ii) as an etching mask during photolithography. Etching is the chemical removal of layers by an etchant from the surface of a wafer, wherein sections of the wafer are protected from the etchant by a mask, such as silicon nitride. After the desired pattern on the wafer has been processed, the remaining photoresist must be removed via wet stripping (via organic or inorganic solutions) or dry stripping (via plasma ions). Dry stripping is considerably more expensive than wet stripping. Therefore, wet stripping is frequently employed to remove the remaining photoresist. However, the organic and inorganic solutions utilized during wet stripping lead to residue(s) on the wafer, which are referred to as “scumming”. These scumming residues are undesired and unacceptable impurities which must be removed from the wafer. Another issue, which arises during photolithography, is undesired extensions at the bottom of the processed photoresist. The undesired extensions are referred to as “footing”. These scumming residues and footing extensions reduce the separation between features of the photoresist, lead to non-uniform critical dimension (CD) and poorer lithographic performance.

The surface of the silicon nitride contains amines which diffuse into a photoresist layers. These photoresist layers are light sensitive materials which are: (i) composed in part of photoacids; and (ii) amenable to photolithography and photoengraving in order to form a patterned coating on a surface. The amines, which diffuse into the photoresist layers, behave as bases (i.e., proton acceptors/lone pair donors) while the photoacids, which already reside within the photoresist layers, behave as acids (i.e., proton donors/lone pair acceptors). The diffusing amines and the residing photoacids have a chemical disposition to react with other proton donors and proton acceptors, respectively. More specifically, the residing photoacids protonate the diffusing amines in the photoresist layers, and thus neutralizing the photoacids. This neutralization reaction (i.e., an acid-base reaction) leads to scumming and footing. Scumming and footing (due to the diffusion of amines into the photoresist layer) render direct the patterning of photoresist on silicon nitride a very challenging endeavor. The photoacids are entities necessary for lithographic patterning of the photoresist which are consumed by the diffused amines during scumming and footing. Scumming, in particular, is the primary reason why silicon nitride is not used EUV lithography, where there is no anti-reflectivity requirements. However, silicon nitride may simplify integration of a circuit by as acting as direct memorization layer. Embodiments of the present invention address the issue of photoresist layer scumming and footing by disclosing a functionalized polymer brush that is 2-3 nanometers (nm) thick between the photoresist and the silicon nitride layers. The functionalized polymer brush is further characterized by the following: (i) containing one or polymer chains, wherein: (a) each polymer chain which is grafted onto the surface of the silicon nitride and (b) an optional polymer chain which is miscible with photoresist layer; (ii) containing acidic functional groups that chemically neutralize basic amines from silicon nitride; and (iii) amenable to molecular weight (MW) tuning that physically hinder amine diffusion into the photoresist layer and thus, prevent amine interaction with the photoacids in the photoresist layer. Accordingly, the polymer brush contains chemical (i.e., neutralizing the amine via acidic functional groups) and physical (i.e., sterically blocking/occluding the amine diffusion via high MW polymers) properties which prevent scumming and footing in photoresist layers. The polymer brush derives from a polymer which is grafted onto a silicon surface via spin coating and subsequent baking processes.

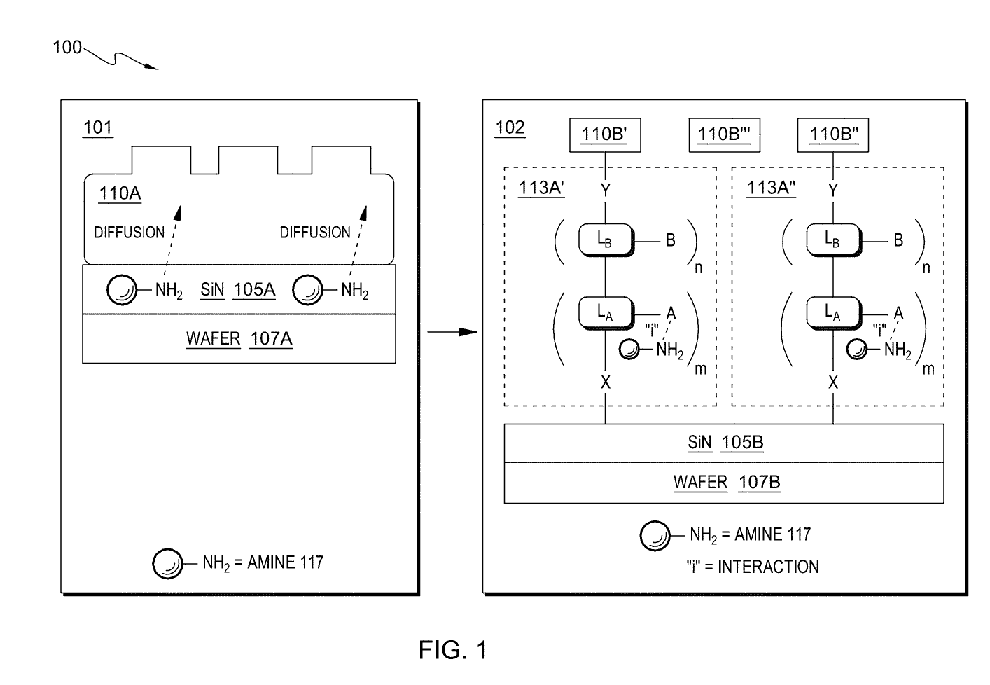

The present invention will now be described in detail by referencing the Figures. FIG. 1A is a diagram illustrating etching environment, generally designated 100, in accordance with one embodiment of the present invention. FIG. 1 provides only an illustration of implementation and does not imply any limitations regarding the environments in which different embodiments may be implemented. Modifications to etching environment 100 may be made by those skilled in the art without departing from the scope of the invention as recited by the claims. In this exemplary embodiment, etching environment 100 includes at least the following elements: a silicon wafer (e.g., wafers 107A and 107B); a silicon nitride surface (i.e., SiN 105A-B); and photoresist layers (resists 110A, 110B′, 110B″, and 110B′″).

Chemical mechanical planarization (CMP) is a process of smoothing surfaces with the combination of chemical and mechanical forces. This combination is a hybrid of chemical etching and free abrasive polishing. In an exemplary embodiment, CMP uses an abrasive and corrosive chemical slurry (which is commonly a colloid) in conjunction with a polishing pad and retaining ring, typically of a greater diameter than a silicon wafer (e.g., wafers 107A-B). The pad (which is not depicted in FIG. 1) and wafers 107A-B are pressed together by a dynamic polishing head and held in place by a plastic retaining ring. The dynamic polishing head is rotated with different axes of rotation (i.e., not concentric). This removes material and tends to even out any irregular topography, making wafers 107A-B flat or planar. This may be necessary to set up the wafer for the formation of additional circuit elements. For example, CMP can bring the entire surface within the depth of field of a photolithography system, or selectively remove material.

Etching is used in microfabrication to chemically remove layers from a surface to create patterns. The pattern is defined by the etching mask, because the parts of the material, which should remain, are protected by the etching mask. In an exemplary embodiment, silicon nitride (e.g., SiN 105A-B) is the etching mask on the surface of a silicon wafer (e.g., wafer 107A-B). The unmasked material can be removed either by wet etching (i.e., chemical techniques) or dry etching (i.e., physical techniques). Wet etching is strongly isotropic and highly selective at creating pattern, wherein the etch rate greatly depends on the material being etched and does not damage the etched material. Dry etching is highly anisotropic but less selective, wherein dry etching is more conducive for transferring small structures in comparison to wet etching. Patterning may also be achieved by lithography. Lithography is used to transfer a pattern from a photomask to the surface of the wafer. For example, the gate area of a transistor is defined by a specific pattern. The pattern information is recorded on a layer of a photoresist which is applied on the top of the wafer. The physical properties of the photoresist change when exposed to light or another source of illumination. The photoresist is either developed by: (i) wet etching or dry etching; or (ii) converted portions of the photoresist to volatile compounds through the exposure of external entities. The pattern, as defined by the photomask, either is removed or remains after development depending on the type of photoresist.

Hardmask layers, such as SiN 105A-B, can be formed using conventional deposition processes (e.g., chemical vapor deposition (CVD), atomic layer deposition (ALD), physical vapor deposition (PVD), plasma enhanced chemical vapor deposition (PECVD), etc.) In an exemplary embodiment, SiN 105A-B are hardmask layers composed of silicon nitride which are deposited/dispersed on wafers 107A-B, respectively, via CVD. In other embodiments, SiN 105A-B may be a hardmask layer composed of titanium nitride, tantalum nitride, and silicon oxynitride, or the like. In some embodiments, the thickness of SiN 105A-B ranges from 5-500 angstroms. If the thickness is below 5 angstroms or above 500 angstroms, then the polymer brush (e.g., brushes 113A′ and 113A″) cannot: (i) graft onto the surface of the silicon nitride and/or (ii) effectively capture amines diffusing from the surface of the silicon nitride. Stated another way, the 5-500 angstrom thickness of SiN 105A-B is a thickness range that allows for the grafting of brushes 113A′ and 113A″ while capturing amines diffusing from the surface of the silicon nitride.

In an exemplary embodiment, a planarized photoresist layer (e.g., resists 110A, 110B′, 110B″, and 110B′″) is patterned using a photolithography technique (e.g., optical lithography or direct write electron beam lithography or the like). For example, resists 110A, 110B′, 110B″, and 110B′″ can be deposited/dispersed onto the planarized layer and lithographically patterned to expose selected portions of the planarized layer. Resists 110A, 110B′, 110B″, and 110B′″ can be formed using conventional deposition techniques such as chemical vapor deposition, plasma vapor deposition, sputtering, dip coating, spin-on coating, brushing, spraying, and other deposition techniques. Following formation of the photosensitive resist layer, the photosensitive resist layer is exposed to a desired pattern of radiation such as 193 nm radiation, X-ray radiation, extreme ultraviolet (EUV) radiation, electron beam radiation or the like. Illustrative examples of 193 nm photoresist layers include a methacrylate polymer, a phenolic based polymer or a copolymer thereof. Other types of organic photoresist layers such as, for example, polyesters can also be employed. Next, the exposed photosensitive resist layer (e.g., resists 110A, 110B′, 110B″, or 110B′″) is developed utilizing a conventional resist development process to expose selected portions of the planarized photoresist layer, which can then be exposed to a wet or dry etchant to form the pattern.

The photoresist layers—resist 110A in system 101 and resists 110B′; 110B″; and 110B′″ in system 102—can be either positive or negative photoresists. A positive photoresist contains portions exposed to light which become soluble to the photoresist developer, whereas the unexposed portions of the photoresist to light remain insoluble to the photoresist developer. A negative photoresist contains portions exposed to light which become insoluble to the photoresist developer, whereas the unexposed portions of the photoresist to light is soluble in the photoresist developer. There are distinct types of photoresists based on chemical structures—photopolymeric, photodecomposing, photocros slinking, and self-assembled monolayer photoresists. Photopolymeric photoresist is a type of photoresist, such as an allyl monomer, which generates free radicals when exposed to light; and initiates the photopolymerization of monomer to produce a polymer. Photopolymeric photoresists are usually used for negative photoresists (e.g., methyl methacrylate). Photodecomposing photoresist is a type of photoresist that generates hydrophilic products under light. Photodecomposing photoresists are usually used for positive photoresists. A typical example is azide quinone (e.g., diazonaphthaquinone (DQ)). Photocrosslinking photoresist is a type of photoresist, which crosslinks a chain to another chain when exposed to light, to generate an insoluble network. Photocrosslinking photoresist are usually used for negative photoresists. For self-assembled monolayer (SAM) photoresists, a SAM is initially formed on the substrate by self-assembly. Then, the SAM covered surface is irradiated through a hardmask, such as silicon nitride, to generate a photo-patterned sample in the irradiated areas. Chemical developer is used to remove the designed part. SAM may be used as both positive and negative photoresists.

As stated above, silicon nitride surfaces contains amines while photoresist layers contain “photoacidic entities”. Amine 117 represents the one or more aliphatic amine structures which can be found on the surface of SiN 105A-B. In other embodiments, non-aliphatic amine structures may be found on the surface of SiN 105A-B, such as aromatic amines. However, aliphatic amines contain basic nitrogen atoms (i.e., a proton accepting amine nitrogen atom) which are rendered more electron rich via electron induction whereas aromatic amines contain basic nitrogen atoms (i.e., a proton accepting amine nitrogen atom) which are rendered more electron poor via electronic resonance delocalization. The aliphatic amine is therefore a stronger base than the corresponding aromatic amine. Accordingly, the aliphatic amine will react more readily with acidic groups within the polymer brush, such as carboxylic acid groups. In the context of this disclosure, “aliphatic” refers to cyclic (e.g., cyclohexyl), saturated (e.g., hexyl), unsaturated (e.g., propenyl and propynyl), linear (e.g., ethyl), or branched (e.g., isopropyl) hydrocarbons. In an exemplary embodiment, SiN 105A is a silicon nitride surface containing amine 117. In this exemplary embodiment, amine 117 is an aliphatic primary amine. For example, amine 117 is ethylamine (CH₃CH₂NH₂). In other embodiments, amine 117 is an aliphatic secondary amine, such as diethyl amine ([CH₃CH₂]₂NH) or methyl tert-butyl amine ([(CH₃)₃C][CH₃]NH). In further embodiments, amine 117 is an aliphatic tertiary amine, such as triethyl amine ([CH₃CH₂]₃N) or Hunig's base ([(CH₃)₂CH]₂[CH₃CH₂]N). In yet further embodiments, amine 117 is an aliphatic quaternary amine salt, such as tetrabutyl ammonium fluoride ([(CH₃CH₂CH₂CH₂)₄N][F]) or tetramethyl ammonium chloride ([(CH₃)₄N][Cl]). The photoacidic entities in the photoresist layers are not explicitly show in FIG. 1. In an exemplary embodiment, the photoacid entities are photoacids (PAHs). A PAH is a molecule which becomes acidic (i.e., a proton donor) upon absorption of light while undergoing proton photodissociation and thermal reassociation. Stated another way, despite PAH being strongly acidic in a light-driven excited state, the protonation step is reversible. In other embodiments, the photoacidic entities are photoacid generators (PAGs). A PAG is a molecule which becomes acidic (i.e., a proton donor) upon absorption of light while undergoing irreversible proton photodissociation. Thermal reassociation is not observed with PAGs. In an exemplary embodiment, triphenylsulfonium triflate [(C₆H₅)₃S⁺][CF₃SO₃⁻] is a PAG which absorbs light at 233 nm which induces a series of reactions to irreversibly generate the highly acidic triflic acid —CF₃SO₃H.

System 101 does not contain a polymer brush while system 102 contains one or more polymer brushes (e.g., brush 113A′ and 113A″). Both system 101 and system 102 contain silicon wafers (e.g., wafer 107A in system 101 and wafer 107B in system 102); silicon nitride (SiN 105A in system 101 and SiN 105B in system 102); photoresist layers (resist 110A in system 101 and resists 110B′, 110B″, and 110B′″ in system 102); and amine 117, which derives from silicon nitrides in systems 101 and 102.

In an exemplary embodiment, where no polymer brush is applied (as depicted in system 101), amine 117 is ethylamine and resist 110A contains triphenylsulfonium triflate. Amine 117 derives from the silicon nitride in SiN 105A. As stated above, EUV lithography is performed at high energy under ambient hydrogen gas. The “nitride” of silicon nitride can react with the hydrogen gas under these conditions to form amine 117. For example, the hydrogens of the NH₂ group of amine 117 most likely originate from hydrogen gas or residual moisture. Additionally, these high energy conditions are able to excite the PAG within resist 110A. In this exemplary embodiment, triphenylsulfonium triflate absorbs excitation radiation to irreversibly generate triflic acid within resist 110A. Amine 117 in the form of ethyl amine, as derived from SiN 105A, is exposed to EUV lithography conditions. Ethyl amine subsequently diffuses/disperses into resist 110A and reacts with the triflic acid in resist 110A. In this exemplary embodiment, triflic acid protonates ethyl amine to furnish ethylammonium triflate ([CH₃CH₂NH₃⁺][CF₃SO₃⁻]). The formation of this salt neutralizes the generated triflic acid, which leads to subsequent scumming and footing in system 101.

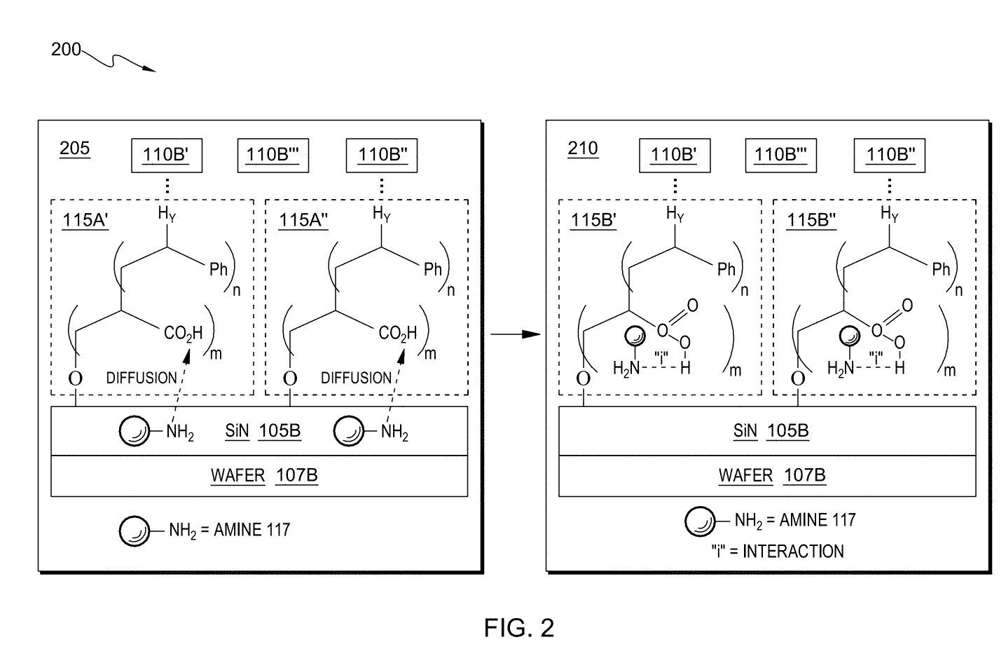

In an exemplary embodiment, where polymer brush(s) are applied (as depicted in system 102), amine 117 is ethylamine and resist 110A contains triphenylsulfonium triflate. The polymer brushes in system 102, as represented by brush 113A′ and brush 113A″ in FIG. 2, reduce and/or eliminate the scumming and footing observed in system 101. As in the case of system 101, system 102 contains amine 117, which derives from a silicon nitride surface —SiN 105B. As stated above, EUV lithography is performed at high energy condition under a hydrogen gas atmosphere. The “nitride” of silicon nitride can react with the hydrogen gas under these conditions to form amine 117. For example, the hydrogens of the NH₂ group of amine 117 most likely originate from hydrogen gas or residual moisture. Additionally, these high energy conditions are able to excite the PAG within resists 110B′, 110B″, and 110B′″. In this exemplary embodiment, triphenylsulfonium triflate absorbs excitation radiation to irreversibly generate triflic acid within resists 110B′, 110B″, and 110B″. Amine 117 in the form of ethyl amine, as derived from SiN 105B exposed to EUV lithography conditions, diffuses out of the surface of SiN 105. In contrast to system 101, amine 117 in system 102 does not reach the photoresist layers of resists 110B′, 110B″, and 110B″. Therefore, in this exemplary embodiment, triflic acid does not protonate ethyl amine to furnish ethylammonium triflate ([CH₃CH₂NH₃⁺][CF₃SO₃⁻]) in the photoresist layers. The formation of the ethylammonium triflate salt has been mitigated or even occluded by the addition of brushes 113A′ and 113A″. Accordingly, the scumming and footing, as would be exhibited in system 101, are not observed in system 102. SiN 105B differs from SiN 105A in that SiN 105B does not contain any amine 117 or has less amine 117 than SiN 105A.

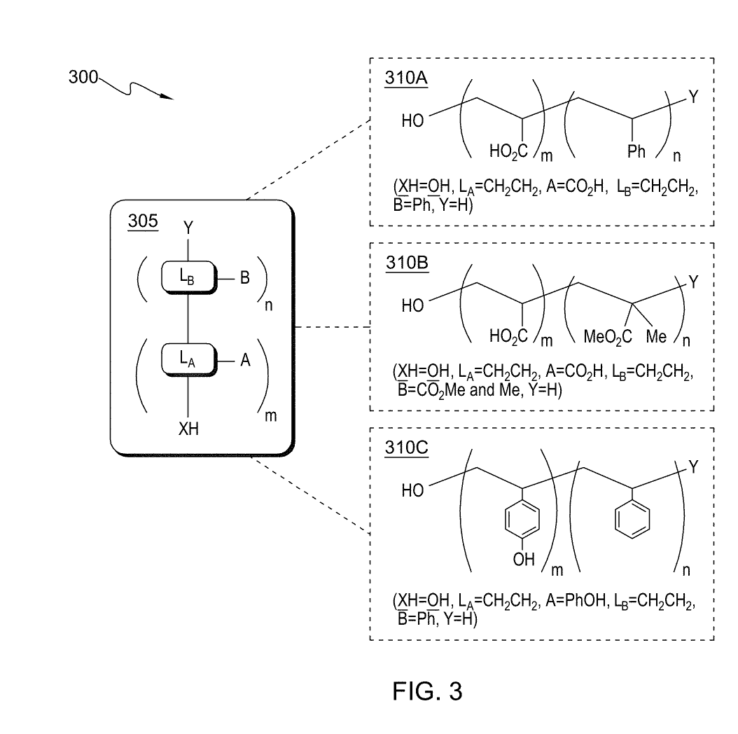

The polymer brushes—brushes 113A′ and 113A″—derive from a polymer with the chemical formula of HX-(L_{A})ₘ-(L_{B})ₐ—Y, wherein there are m units of the L_{A} structural unit containing functional group A and there are n units of the L_{B} structural unit containing functional group B. The polymers from which brushes 113A′ and 113A″ derive from are described in more detail with respect to FIG. 2 and FIG. 3. The X group of the XH group in HX-(L_{A})ₘ-(L_{B})ₙ-Y grafts onto SiN 105B, wherein X is oxygen (O). Grafting involves forming a chemical bond, and may also be referred to as “chemically grafting”. A Si—O chemical bond is formed by virtue of grafting the polymer brush onto a silicon nitride surface, such as SiN 105B. The Y group of brushes 113A′ and 113A″ is a hydrogen atom. The L_{B} and Y groups of brushes 113A′ and 113A″ form a miscible component with resists 110B′ and 110B″, respectively. The Y group does not form a chemical bond with resists 110B′ and 110B″. Instead, the Y group connect brushes 113A′ and 113A″ by immersion (i.e., “wetting” to resists 110B′ and 110B″, respectively. The combination of the polymer brush; Si—X bond (which chemically connects the polymer brush to silicon nitride); and Y-photoresist interaction (which physically connects the polymer brush to the photoresist layer) create a stack which traps/sequesters the diffusing amine 117 by interaction “i”. A “dotted line box” is used to depict that a polymer brush is contained within each stack.

More specifically, the A functional group of structural unit L_{A} traps amine 117, wherein A is a functional group, such as a carboxylic acid group (—COOH), interacts with amine 117. In an exemplary embodiment, A=COOH and thus A in FIG. 1 protonates amine 117 to trap amine 117 in brushes 113A′ and 113A″. The ionic salt of the protonated version of amine 117, which has been electrostatically countered by the deprotonated version of the carboxylic acid group (i.e., a carboxylate group), is sequestered by L_{A} in brushes 113A′ and 113A″. In this embodiment, “i” in FIG. 1 is an ionic interaction between protonated amine 117 and deprotonated carboxylate. The protonated version of amine 117 (i.e., “ammonium 117”) and the deprotonated version of COOH (i.e., “carboxylate A”) are not drawn explicitly in FIG. 1.

In another exemplary embodiment, A=phenyl (Ph) and thus, A in FIG. 1 sterically hinders amine 117 from further diffusing into resists 110B′ and 110B′″. As observed when A is an acidic functional group, amine 117 is sequestered by L_{A} in brushes 113A′ and 113A″ where A=Ph. In this embodiment, “i” in FIG. 1 is the steric interactions between the phenyl groups and amine 117. The phenyl groups are sterically hindering to amine 117 and thus, mitigate and modulate the diffusion of amine 117 into resists 110B′ and 110B″. The steric hindrance of amine 117 by A is not drawn explicitly in FIG. 1.

In yet another exemplary embodiment, A=phenol (PhOH) and thus, A in FIG. 1 hydrogen bonds with amine 117. As observed when A is carboxylic acid functional group, amine 117 is sequestered by L_{A} in brushes 113A′ and 113A″ where A=PhOH. In this embodiment, “i” in FIG. 1 is the hydrogen bonding interaction where amine 117 behaves as the hydrogen bond acceptor and PhOH behaves as the hydrogen bond donor. The hydrogen bonding between amine 117 and PhOH in L_{A} is not drawn explicitly in FIG. 1.

FIG. 2 is a diagram illustrating amine trapping by the polymer brush, in accordance with an embodiment of the present invention.

Sequestration process 200 depicts the chemical trapping/sequestration of amine 117. System 205 depicts a two stack structure on wafer 107B and SiN 105B prior to amine 117 diffusing out of the surface of SiN 105B whereas, system 210 depicts a two stack structure on wafer 107B and SiN 105B after amine 117 diffuses out of the surface of SiN 105B. Both systems 205 and 210 contain resist 110B′″, which is not attached via immersion to any stack. Polymer brushes 115A′, 115A″, 115B′, and 115B″ derive from the polymer described in FIG. 1 as HX-(L_{A})ₘ-(L_{B})ₙ-Y, wherein X═O; L_{A}=ethylene (CH₂CH₂) backbone where A=—COOH with m units; L_{B}=ethylene (CH₂CH₂) backbone where A=Ph with n units; and Y═H. L_{A} derives from polyacrylic acid whereas L_{B} derives from polystyrene. Brushes 115A′, 115A″, 115B′, and 115B″ are 2-3 nm in thickness upon grafting onto the surface of SiN 105B through an oxygen (O) atom, as depicted in system 205 and system 210 in FIG. 2.

In an exemplary embodiment, brush 115A′ and resist 110B′ construct a first stack in system 205, wherein the oxygen (O) of polymer brush 115A′ is chemically grafted onto silicon of SiN 105B and H_{Y} of polymer brush 115A′ is physically immersed into resist 110B′. In the same exemplary embodiment, polymer brush 115A″ and resist 110B′″ construct a second stack in system 205, wherein the oxygen (O) of polymer brush 115A″ is chemically grafted onto silicon of SiN 105B and H_{Y} of polymer brush 115A″ is physically immersed into resist 110B′″. The oxygen atom (O), which attaches brushes 115A′ and 115A″ to SiN 105B, corresponds to “X” in FIG. 1. H_{Y} is a hydrogen atom which corresponds to “Y” in FIG. 1. The subscript of “Y” in H_{Y} is used to distinguish this hydrogen atom from: (i) the —COOH hydrogen atom in brushes 115A′, 115A″, 115B′, and 115B″; and (ii) the —NH₂ hydrogen atoms in amine 117. Amine 117 moves from the surface of SiN 105B to brush 115A′ and 115A″ via diffusion, as depicted in FIG. 2. After the diffusion of amine 117, system 210 results where brushes 115A′ and 115A″ furnish brushes 115B′ and 115B″, respectively. Similar to brushes 115A′ and 115A″, polymer brush 115B′ and resist 110B′ construct a first stack in system 210, wherein the oxygen (O) of polymer brush 115B′ is chemically grafted onto silicon of SiN 105B and H_{Y} of polymer brush 115B′ is physically immersed into resist 110B′. In the same exemplary embodiment, polymer brush 115B″ and resist 110B″ construct a second stack in system 210, wherein the oxygen (O) of polymer brush 115B″ is chemically grafted onto silicon of SiN 105B and H_{Y} of polymer brush 115B″ is physically immersed into resist 110B′″. Brushes 115B′ and 115B″ differ from brushes 115A′ and 115A″ in that amine 117 is trapped in brushes 115B′ and 115B″ by interaction “i”. A “dotted line box” is used to depict that a polymer brush is contained within each stack in systems 205 and 210. Unlike a dielectric spacer layer or dielectric antireflective coating (DARC), brushes 115B′ and 115B″ prevent the diffusion of amine 117 into the photoresist layers while also modulating the amount of diffusion of amine 117 from the surface of SiN 105B.

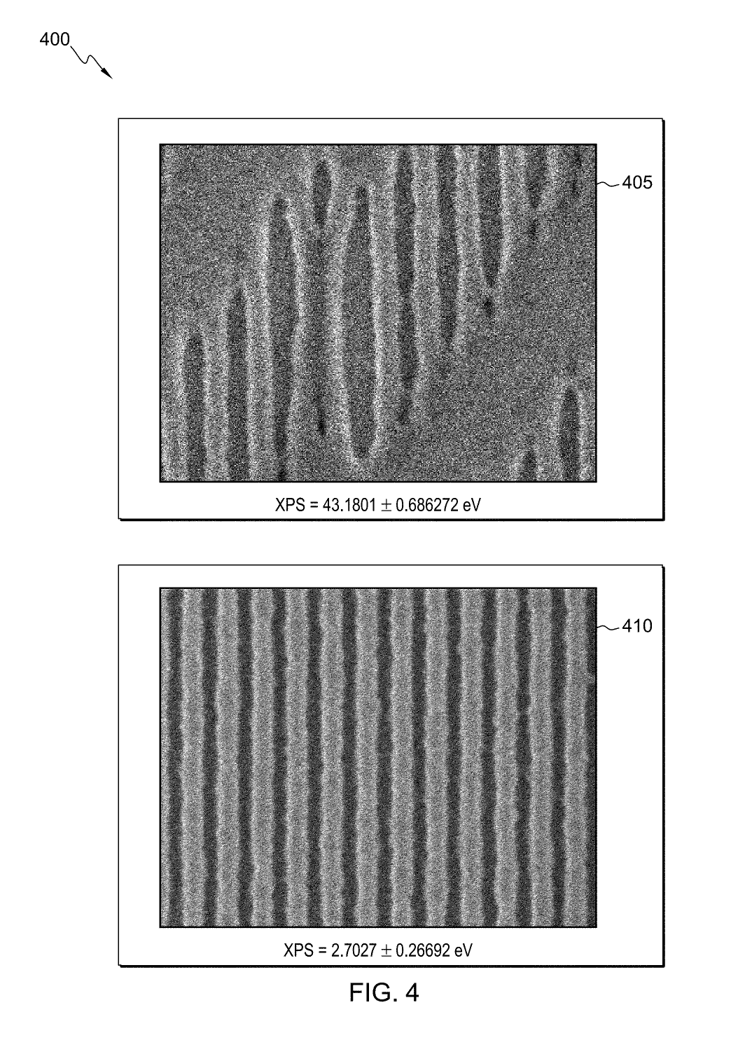

By varying the molecular weight or acidity of brushes 115A′ and 115B″, the amount of amine 117 content which is trapped by interaction “i” can be controlled (i.e., modulating the amount of diffusion of amine 117 from the surface of SiN 105B). In an exemplary embodiment, system 210 contains a type of amine 117 which has branched moieties. For example, brushes 115B′ and 115B″, which have a molecular weight of 13000 Daltons and sterically hindering acids (e.g., 4-tert-butyl-2,6-mesatyl-phenyl phosphonic acid), are used instead of an acrylic acid group. As this branched type of amine 117 diffuses from the surface of SiN 105B, brushes 115B′ and 115B″, which have the sterically hindering acids and the large molecular weight of 13000 Daltons, trap the branched type of amine 117 via interaction “i”. In another instance, polymer brushes 115B′ and 115B″ have a molecular weight of 10000 Daltons and the same sterically hindering acids. The lower molecular weight variant of brushes 115B′ and 115B″ also traps the branched type of amine 117 diffusing from the surface of SiN 105B. Using x-ray photoelectron spectroscopy (XPS), as discussed in more detail with respect to FIG. 4, the amount of amine 117 residing on the surface of SiN 105B can be compared between the lower molecular weight and higher molecular variant of brushes 115B′ and 115B″. Higher XPS energy values are indicative of increased amine (e.g., amine 117) content on the surface of SiN 105B. In this example, the lower molecular weight variant of brushes 115B′ and 115B″ traps less amine 117 than the higher molecular weight variant of brushes 115B′ and 115B″. Therefore, the surface of SiN 105B exhibits lower XPS energy values for the higher molecular weight variant of brushes 115B′ and 115B″ than for the lower molecular weight variant of brushes 115B′ and 115B″. This example represents modulating the amount of amine diffusion from a silicon nitride surface by varying the molecular weight of the polymer brush.

In an exemplary embodiment, the COOH group in brushes 115B′ and 115B″ are deprotonated by amine 117. Interaction “i” is ionic as the COOH group has been deprotonated to make carboxylate (—COO⁻) and amine 117 has been protonated to make ammonium (R—NH₃⁺). Stated another way, trapped amine 117 by the —COOH group leads to “i” to yield the ionic salt via:

R—COOH+R—NH₂→(R—NH₃⁺) (R—COO⁻) (eq. 1)

The resulting salt in eq. 1 is not found in the photoresist layer. Rather, the resulting salt in eq. 1 is found sequestered in the polymer brushes (e.g., brushes 115B′ and 115B″ in FIG. 2). Therefore, the polymer brushes appended to SiN 105B (e.g., brushes 115A′, 115A″, 115B′, and 115B″ in FIG. 2) mitigate scumming and footing in the photoresist layers (e.g., resist 110B′, 110B″, and 110B′″).

The molecular weight and functional groups are key features of brushes 115B′ and 115B″ that are able to modulate the diffusion of amine 117. In some embodiments, higher molecular weight variants of brushes 115B′ and 115B″ prove to be too sterically imposing for the diffusion of amine 117. In these instances, “i” is steric hindrance to mitigate and modulate the diffusion of amine 117. As indicated above with eq. 1, acidic functional groups can protonate amine 117 to trap diffusing amine 117. In these instance, “i” is a chemical interaction by ionization or hydrogen bonding to mitigate and modulate the diffusion of amine 117.

FIG. 3 is a diagram illustrating the polymers used to derive the polymer brushes that sequester amine, in accordance with an embodiment of the present invention.

Structures 300 are the polymers from which the polymer brushes (e.g., brushes 113A′, 113A″, 115A′, 115A″, 115B′, and 115B″) derive from polymeric structure 305. Polymeric structure 305 represents the generic structure of the polymers used to derive polymer brushes. In an exemplary embodiment, polymeric structure 305 has the chemical structure of HX-(L_{A})ₘ-(L_{B})ₙ-Y. L_{B} may or may not be incorporated into polymeric structure 305.

In some embodiments, L_{B} is incorporated into polymeric structure 305 as depicted in FIG. 3. In such instances, polymeric structure 305 is HO-(LA)ₘ-(L_{B})ₙ-Y (which is explicitly depicted in FIG. 3). For example, the polymer HO—(CH₂CH₂PhOH)ₘ—(CH₂CH₂Ph)ₙ-H corresponds to X═O; Y═H; L_{A} is an ethylene backbone wherein A is PhOH; and L_{B} is an ethylene backbone wherein B is Ph. L_{A} derives from poly-hydroxy styrene and L_{B} derives from polystyrene. The variant of polymeric structure 305 corresponding HO-(L_{A})ₘ-(L_{B})ₙ Y contains: (i) L_{A} structural units which are sterically hindering and proton donating to trap amine 117 in a polymer brush, wherein L_{A}=CH₂CH₂PhOH; and (ii) L_{B} structural units able to wet photoresist layers in conjunction with Y (i.e., immerse portions of “O-(L_{A})ₘ-(L_{B})ₙ-Y” of the polymer brush into the photoresist layers). The “O” of HO-(L_{A})ₘ-(L_{B})ₙ-Y grafts onto the silicon nitride surface to form Si—O chemical bonds. In another embodiment, the polymer HO—(CH₂CH₂PhOH)ₘ—(CH₂CHMeCO₂Me)ₙ-Y corresponds to: X═O; Y═H; L_{A} is an ethylene backbone wherein A is PhOH; and L_{B} is an ethylene backbone, wherein B is Me, CO₂Me. L_{A} derives poly-hydroxy styrene and L_{B} derives from poly-methyl methacrylate (PMMA). Unlike dielectric spacer layers on a dielectric antireflective coating (DARC), polymeric structure 305 is amenable to processing which yield polymer brushes, such as brushes 113A′, 113A′, 115A′, 115A″, 115B′, and 115B″, that 2-3 nm thick.

In some embodiments, L_{B} is not incorporated into polymeric structure 305 as not depicted in FIG. 3. In such instances, polymeric structure 305 is HO-(L_{A})ₘ-Y (which is not explicitly depicted in FIG. 3). For example, the polymer HO—(CH₂CH₂PhOH)ₘ—H corresponds to X═O, Y═H, and L_{A} is an ethylene backbone wherein A is PhOH. L_{A} derives from poly-hydroxy styrene. The variant of polymeric structure 305 corresponding HO-(L_{A})ₘ-Y contains L_{A} structural units which are sterically hindering and able to wet photoresist layers in conjunction with Y (i.e., immerse portions of HO-(L_{A})ₘ-Y into the photoresist layers), wherein L_{A}=CH₂CH₂PhOH. The “O” of HO-(L_{A})ₘ-Y grafts onto the silicon nitride surface to form Si—O chemical bonds. In another embodiment, the polymer HO—(CH₂CH₂COOH)ₘ—H corresponds to X═O, Y═H, and L_{A} is an ethylene backbone wherein A is COOH. L_{A} derives from poly-acrylic acid.

HX-(L_{A})ₘ-(L_{B})ₙ-Y is a copolymer consisting of two types of constituent units (which are also referred to as structural units). The two structural units are L_{A} and L_{B}, wherein A and B are functional groups of a polymer backbone. Polymeric structure 305 can adopt different arrangements of the structural units. In some embodiments, polymeric structure 305 is referred to as a type of “alternating copolymer” with regularly alternating L_{A} and L_{B} units. In some embodiments, polymeric structure 305 is referred to as a type of “periodic copolymer” with L_{A} and L_{B} units arranged in a repeating sequence (e.g. (L_{A}-L_{B}-L_{A}-L_{B}-L_{B}-L_{A}-L_{A}-L_{A}-L_{A}-L_{B}-L_{B}-L_{B})). In some embodiments, polymeric structure 305 is referred to as a type of “statistical copolymer” in which the sequence of structural units follows a statistical rule. If the probability of finding a given type of structural unit at a particular point in the chain is equal to the mole fraction of that structural unit in the chain, then polymeric structure 305 may be referred to as a truly “random copolymer”. In some embodiments, polymeric structure 305 is referred to as a type of “block copolymer” where two or more homopolymer subunits are linked by covalent bonds. The union of the homopolymer subunits may require an intermediate non-repeating subunit, known as a junction block. Block copolymers with two or three distinct blocks are called diblock copolymers and triblock copolymers, respectively. In some embodiments, polymeric structure 305 may be arranged as branched copolymer instead of linear copolymers. As depicted in FIG. 3, polymeric structure 305 is a single main chain as observed in the case of linear copolymers. If polymeric structure 305 is a type of branched copolymer, one or more polymeric side chains are appended a single main chain. Other special types of branched copolymers include star copolymers, brush copolymers, and comb copolymers. In gradient copolymers the structural unit composition changes gradually along the chain.

In exemplary embodiment, polymer 310A is HO—(CH₂CH₂COOH)ₘ—(CH₂CH₂Ph)ₙ-H. In the instance of polymer 310A, HX-(L_{A})ₘ-(L_{B})ₙ-Y is a copolymer containing the monomer of poly-acrylic acid and the monomer of polystyrene, wherein A=COOH; B=Ph; X═O; and Y═H. The monomer of poly-acrylic acid corresponds to the ethylene backbone and COOH group in L_{A}, whereas the monomer of polystyrene corresponds to the ethylene back and -Ph group in L_{B}. Poly-styrene derived polymers, such as polymer 310, have a molecular weight distribution of 5000 Daltons (D) to 15000 D. The phenyl (Ph) groups within polymer 310 are sterically imposing. In turn, the Ph groups in polymer 310A sterically hinder amine 117 diffusion into the photoresist layer. The Ph groups in L_{B} in conjunction with Y render the end of polymer 310A associated with L_{B} more miscible with photoresist layers. Additionally, the COOH groups in polymer 310A are able to protonate amine 117. In turn, the COOH groups in polymer 310A chemically hinder amine 117 diffusion into the photoresist layer, as described above. The polydispersity index (PDI) for polymer 310A is less than 2.

In exemplary embodiment, polymer 310B is HO—(CH₂CH₂COOH)ₘ—(CH₂CHMeCO₂Me)ₙ-H. In the instance of polymer 310B, HX-(L_{A})ₘ-(L_{B})ₙ-Y is a copolymer containing the monomer of poly-acrylic acid and the monomer of poly-methyl methacrylate (PMMA), wherein A=COOH; B=Me,CO₂Me; X═O; and Y═H. The monomer of poly-acrylic acid corresponds to the ethylene backbone and COOH group in L_{A} whereas the monomer of polystyrene corresponds to the ethylene back and Me and CO₂Me groups in L_{B}. PMMA derived polymers, such as polymer 310B, have a molecular weight distribution of 3000 Daltons (D) to 15000 D. The Me and CO₂Me groups in L_{B} in conjunction with Y render the end of polymer 310B associated with L_{B} more miscible with photoresists layers. Additionally, the COOH groups in polymer 310B are able to protonate amine 117. In turn, the COOH groups in polymer 310B chemically hinder amine 117 diffusion into the photoresist layer, as described above. The polydispersity index (PDI) for polymer 310B is less than 2.

In exemplary embodiment, polymer 310C is HO—(CH₂CH₂PhOH)ₘ—(CH₂CH₂Ph)ₙ-H. In the instance of polymer 310C, HX-(L_{A})m-(L_{B})ₙ-Y is a copolymer containing the monomer of poly-hydroxy styrene and the monomer of polystyrene, wherein A=PhOH; B=Ph; X═O; and Y═H. The monomer of poly-hydroxy styrene corresponds to the ethylene backbone and -PhOH group in L_{A} whereas the monomer of polystyrene corresponds to the ethylene back and Ph group in L_{B}. Poly-styrene derived polymers, such as polymer 310C, have a molecular weight distribution of 5000 Daltons (D) to 15000 D. The phenol within polymer 310 are sterically imposing. More specifically, the phenyl portion of the -PhOH groups in polymer 310C sterically hinder amine 117 diffusion into the photoresist layer. The Ph groups in L_{B} in conjunction with Y aid in making the end of polymer 310C associated with L_{B} more miscible with photoresists layers. Additionally, the -PhOH (i.e., phenol) groups in polymer 310C are able to protonate or hydrogen bond with amine 117. In turn, the -PhOH groups in polymer 310C also chemically hinder amine 117 diffusion into the photoresist layer, as described above. The polydispersity index (PDI) for polymer 310 is less than 2.

FIG. 4 is a diagram comparing scanning electron microscope images where the polymer brush is applied and the polymer brush is not applied, in accordance with an embodiment of the present invention.

Visualization environment 400 illustrates the resolution of silicon nitride surfaces using scanning electron microscope (SEM) images. EUV resists are patterned on silicon nitride that: (i) contain grafted polymer brushes deriving from a 5000 D molecular weight poly-hydroxyl styrene polystyrene copolymer; and (ii) do not contain grafted polymer brushes.

Image 405 is the SEM taken where a polymer brush, such as brushes 113A′, 113A″, 115A′, 115A″, 115B′, and 115B″, has not been grafted onto the silicon nitride surface. Without the grafted polymer brushes on the silicon nitride surface, scumming and footing occur in a system such as system 101 in FIG. 1. System 101 in FIG. 1 corresponds to image 405. In contrast to image 405, image 410 is the SEM take where a polymer brush, such as brushes 113A′, 113A″, 115A′, 115A″, 115B′, and 115B″, has been grafted onto the silicon nitride surface. As a result of grafting the polymer brushes onto the silicon nitride surface, scumming and footing do not occur in a system such as system 102 in FIG. 1. System 102 corresponds to image 410. The polymer brush associated with system 102 mitigates scumming and footing and thus enables a good process window for x-ray photoelectron spectroscopy (XPS). The omission of the polymer brush associated with system 101 facilitates scumming and footing and thus prevents a good process window for XPS. The XPS data to analyze the surface atomic composition is collected at a fixed angle of 54.7° and the X-rays, which impinge upon the surfaces of system 101 and 102, are generated from an aluminum anode at 1486.7 eV.

In an exemplary embodiment, the XPS data for the silicon nitride surface of system 101, which corresponds to image 405, is 43.1801±0.686272 eV whereas the XPS data for the silicon nitride surface of system 102, which corresponds to image 410, is 2.7027 eV±0.26692 eV. Higher XPS energy values are indicative of increased amine (e.g., amine 117) content on the silicon nitride surface. The polymer brush of system 102 sequesters/traps amines which diffuse from the surface of silicon nitride. The lack of the polymer brush in system 101 allows the amine to diffuse from the surface of the silicon nitride into the photoresist. Amines are removed from the silicon nitride surface of system 102 whereas amines are not getting removed from the silicon nitride surface of system 101. Accordingly, image 410, which corresponds to system 102, exhibits a significantly lower energy from the XPS radiation than image 410, which corresponds to system 101.

In an exemplary embodiment, scumming and footing results when amines are diffusing into the photoresist layers. The lack of a polymer brush results in amines remaining on and otherwise unmoved from the surface of silicon nitride as observed in system 101. Scumming and footing are mitigated or prevented when amines are getting removed from the surface of silicon nitride and not diffusing into the photoresist layers by virtue of including a polymer brush, as observed in system 102. Scumming in system 101 leads to image 405, which has poorly resolved features and trenches. The lack of scumming in system 102 leads to image 410, which has well-resolved features and trenches. Image 410 is resolved at the 36 nm pitch (full distance of line and space) level. Furthermore, image 410 indicates that EUV patterning schemes are possible using the polymer brushes described in FIG. 1 and FIG. 2.

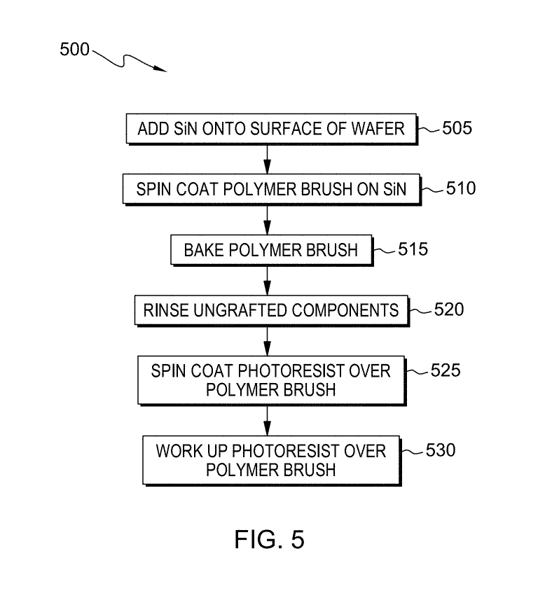

FIG. 5 is a flowchart 500 describing the operation steps involved the formation of a polymer brush grafted system, in accordance with an embodiment of the present invention

Flowchart 500 summarizes the processing steps implemented during lithographic etching. The actor of this invention which is performing the steps of flowchart 500 is a plurality of fabrication devices for performing the techniques with respect to fabrication processing. Fabrication processing involves the following techniques/processes applied on a uniformly doped silicon wafer (i.e., semiconductor fabrication)—lithography; etching; deposition; oxidation; chemical mechanical planarization; ion implantation; and diffusion—to furnish integrated circuits, wherein the integrated circuits may contain multiple units of transistors. This is not an exhaustive list of techniques/processes included within fabrication processing but rather a list of commonly used techniques as understood in the art. Furthermore, the term “fabrication processing” implies a device or set of devices or any type of equipment used to implement the said techniques/processes, as understood in the art.

In step 505, fabrication processing invokes a plurality of fabrication devices to add SiN, as in silicon nitride, (e.g., SiN 105A and 105B from FIG. 1) onto the surface of a wafer (wafer 107A and 107B from FIG. 1). In this embodiment, the plurality of fabrication devices adds silicon nitride (SiN) by performing a dehydration bake. The dehydration bake removes water from the surface of the wafer by baking at temperatures of 200° C. to 400° C., usually for 30 to 60 minutes. The wafer is then allowed to cool (preferably in a dry environment) and promptly coated with silicon nitride. Delaying the addition of silicon nitride to the wafer may introduce undesired moisture to the system. It is important to note that water will re-adsorb on the substrate surface if left in a humid (non-dry) environment. A dehydration bake may also remove organic contaminants by volatilizing these organic contaminants. Thus, the dehydration bake is further cleaning the (silicon) wafer. Often, the typical sequence of processing steps involves some type of high temperature process immediately before coating with photoresist, for example thermal oxidation. If the surface of the wafer is coated immediately after the high temperature step, the dehydration bake can be eliminated. However, a typical dehydration bake does not completely remove water from the surface of silicon wafer substrates (e.g., silicon, polysilicon, and silicon oxide) or silicon nitride. Surface silicon atoms bond strongly with a monolayer of water forming silanol groups. Bake temperatures in excess of 600° C. are required to remove this final layer of water. Furthermore, the silanol quickly reforms when the substrate is cooled in a non-dry environment. In other embodiments, the plurality of fabrication devices add SiN by performing chemical modifications. Since the baking approach may prove to be impractical, the preferred method of removing this silanol is by performing chemical modifications. Adhesion promoters are used to react chemically with surface silanol and replace the —OH group of silanol with an organic functional group that offers good adhesion to a photoresist layer, unlike the replace —OH group. Silanes are often used for this purpose, the most common being hexamethyl disilizane (HMDS).

In step 510, fabrication processing invokes a plurality of fabrication devices to spin coat a polymer brush on silicon nitride. In this embodiment, the plurality of fabrication devices spin coat the polymer brush on the silicon nitride by initially dissolving a polymer in coating solvent. The polymer brush derives from a polymer structure (as described in FIG. 3), which have the formula of HO-(L_{A})m-(L_{B})ₙ-Y or HO-(L_{A})m-Y. In an exemplary embodiment, a casting solvent (e.g., propylene glycol methyl ether acetate; ethyl lactate; n-butyl acetate; and gamma butyric lactone) is used to dissolve a polymer, such as polymers 310A-C. A thin, uniform coating of the polymer brush at a specific, well controlled thickness is achieved by spin coating. More specifically, a centrifugal force is applied by a machine, referred to as a spin coater, or spinner. Higher angular speeds lead to thinner coatings. The polymer used to derive the polymer brush is rendered into a liquid form by dissolving the solid components in the casting solvent. For example, the polymer solution is 2-10 percent solution by weight in the casting solvent. The polymer solution is poured onto the silicon nitride, which is then spun on a turntable at a high speed producing the desired film. Stringent requirements for thickness control and uniformity and low defect density call for particular attention to be paid to this process, where a large number of parameters can have significant impact on polymer brush thickness uniformity and control. The speed in which the polymer solution is spun on the turn table influences the thickness of the resulting film. Depending on the semiconductor manufacturer or the other components within a desired product, it may be essential that the film be of a certain thickness. For example, if the film is too thick, then the polymer brush may leach into the silicon nitride surface.

In step 515, fabrication processing invokes a plurality of fabrication devices to bake the polymer brush. In some embodiments, the plurality of fabrication devices bake the polymer brush in order to chemically graft the polymer brush onto the surface of silicon nitride. Baking the polymer brush is also referred to a post-apply bake process, and is also called a “softbake” or a “prebake”. In some embodiments, baking is accomplished by utilizing a convection oven or hotplate oven. Baking involves: (i) drying the dissolved polymer after spin coat by removing this excess solvent; and (ii) grafting the oxygen (O) of the polymer brush onto the silicon nitride surface. Furthermore, the hydrogen from “OH” in HO-(L_{A})m-(L_{B})ₙ-Y or HO-(L_{A})m-Y may be absorbed by the amines on the surface of silicon nitride. The amines, such as amine 117, are acting as proton sponges. In other embodiments, the hydrogen from “OH” in HO-(L_{A})m-(L_{B})ₙ-Y or HO-(L_{A})m-Y may be used to generate hydrogen gas or water during the grafting of the oxygen from “OH” in HO-(L_{A})m-(L_{B})ₘ-Y or HO-(L_{A})m-Y onto the surface of silicon nitride. For the poly-hydroxy styrene variant of polymeric structure 305, such as polymer 310C, the baking temperatures vary from 200-250° C. in order to graft the oxygen atom onto the silicon nitride surface (as shown in FIG. 2). For the PMMA variant of polymeric structure 305, such as polymer 310B, the baking temperatures are performed from room temperature to 100° C. in order to graft the oxygen onto the silicon nitride surface. Grafting removes the hydroxyl group functionality (“—OH”) of HO-(L_{A})m-(L_{B})ₙ-Y or HO-(L_{A})m-Y by creating silicon-oxygen (Si—O) bonds. The oxygen (O) derives from the hydroxyl group of HO-(L_{A})m-(L_{B})ₙ-Y or HO-(L_{A})m-Y while the silicon (Si) derives from the silicon nitride surface. As mentioned above, the removal of hydroxyl groups offers better adhesion of substrates to the photoresist layer.

In step 520, fabrication processing invokes a plurality of fabrication devices to rinse ungrafted components. In this embodiment, the plurality of fabrication devices rinse the ungrafted components (i.e., polymers which do not form a Si—O bond with the silicon nitride) using a casting solvent. More specifically, not all of the polymer is grafted on the silicon nitride surface through the oxygen (“O”) from the hydroxyl (“—OH”) in the polymer HO-(L_{A})m-(L_{B})ₙ-Y or HO-(L_{A})m-Y. Additional quantities of casting solvents described in step 505, such as propylene glycol; methyl ether acetate; ethyl lactate; n-butyl acetate; and gamma butyric lactone, are added to remove the ungrafted polymer, such as polymers 310A-C. The grafted polymer brush, such as brushes 113A′, 113A″, 115A′, 115A″, 115B′ and 115B″ are unreactive and insoluble in the casting solvents. Therefore, the grafted polymer brushes onto the silicon nitride are unaffected by the casting solvents and the formed silicon-oxygen bond is maintained.

In step 525, fabrication processing invokes a plurality of fabrication devices to spin coat a photoresist over a polymer brush. In this embodiment, the plurality of fabrication devices spin coat the photoresist over the polymer brush by initially dissolving a photoresist in coating solvent. More specifically, a casting solvent (e.g., propylene glycol; methyl ether acetate; ethyl lactate; n-butyl acetate; and gamma butyric lactone) is used to dissolve photoresists, such as resist 110B′, 110B″, and 110B′″. A thin, uniform coating of the photoresist at a specific, well controlled thickness is achieved by spin coating. The photoresist is rendered into a liquid form by dissolving the solid components in a casting solvent. The photoresist solution is subsequently poured onto the silicon nitride, which is then spun on a turntable at a high speed producing the desired film. Stringent requirements for thickness control and uniformity and low defect density call for particular attention to be paid to this process, where a large number of parameters can have significant impact on polymer brush thickness uniformity and control.

In step 530, fabrication processing invokes a plurality of fabrication devices to work up the photoresist over the polymer brush. In this embodiment, the plurality of fabrication devices work up the photoresist over the polymer brush by post-apply bake processes. The post-apply bake processes, which also referred to as “softbakes” or a “prebakes”, involve drying the dissolved photoresist after spin coat by removing excess solvent. The main reason for reducing the solvent content is to stabilize the photoresist film (e.g., resists 110B′, 110B″, and 110B′″). At room temperature, an unbaked photoresist film will lose solvent by evaporation, thus changing the properties of the film with time. By baking the photoresist, the majority of the solvent is removed and the film becomes stable at room temperature. There are four major effects of removing solvent from a photoresist film: (i) the film thickness is reduced; (ii) the post-exposure bake and development properties are changed; (iii) the adhesive properties are improved; and (iv) the film becomes less tacky and thus less susceptible to particulate contamination. Typical prebake processes leave between 3 and 8 percent residual solvent in the photoresist film, sufficiently small to keep the film stable during subsequent lithographic processing. In some embodiments, the L_{B} and Y groups of the polymer brushes in FIG. 2 (e.g., brushes 115B′ and 115B″) are miscible with the photoresists (e.g., resists 110B′ and 110B″) and remain unaltered by the post-apply bake process. System 102 is furnished upon performing steps 505, 510, 515, 520, 525, and 530.

Where the polymer is HO—(CH₂CH₂COOH)ₘ—(CH₂CH₂Ph)ₙ-H (polymer 310A), the following procedure is carried out to construct a photoresist system containing one or more polymer brushes. This procedure involves the following steps below.

Deposit 5-20 nm of silicon nitride onto a silicon water surface via CVD at temperatures ranging from 200-400° C. In other embodiments, PVD or PECVD are used to deposit 5-20 nm of silicon nitride on a silicon wafer surface. (See step 505 of FIG. 5.)

Dissolve polymer 310 in 100 milliliters (mL) of propylene glycol such that the polymer solution is 2% by weight in the casting solvent, which is propylene glycol. (See step 510 of FIG. 5.)

Pour the polymer 310-propylene glycol solution on the based silicon nitride surface (see step 515 of FIG. 5).

Spin coat the polymer 310-propylene glycol solution at an angular speed of 1500 revolutions per minute (RPM) over 1 minute at room temperature. (See step 515 of FIG. 5.)

In a convection oven, heat the spin coated polymer 310A on the silicon nitride surface from 75-200° C. over 1-5 minutes to graft polymer 310A onto the silicon nitride surface. (See step 515 of FIG. 5.)

Rinse ungrafted polymer 310 with 20-50 mL of propylene glycol at room temperature. The rinsed ungrafted polymer 310 which has been dissolved in the propylene glycol is collected into a beaker and disposed. (See step 520 of FIG. 5.)

Dissolve a photoresist in 100 mL of propylene glycol such that the photoresist solution is between 2.5-10% by weight in the casting solvent. (See step 525 of FIG. 5.)

Pour the photoresist solution on the based silicon nitride surface and spin coat the polymer solution at an angular speed of 1500 rpm over 1 minute at room temperature. (See step 525 of FIG. 5.)

In a convection oven, heat the spin coated photoresist solution to a temperatures between 80-150° C. over 1 minute. (See step 530 of FIG. 5.) System 210 of FIG. 2 is furnished when a variant of polymer 310A with a molecular weight between 5000 D-15000 D is exposed to steps 510, 515, 520, 525, and 530 after depositing silicon nitride over a silicon wafer surface. The polymer brushes, which derive from polymer 310A, are: (i) grafted onto the surface of silicon nitrides via silicon-oxygen bonds; and (ii) immersed with the photoresists. These polymer brushes have a thickness of 2-3 nm. (See brushes 115B′ and 115B″ of FIG. 2.)

What is claimed is:

1. A method comprising:
dissolving a plurality of polymer brushes in a casting solvent, wherein the plurality of polymer brushes contain a first constituent unit and a second constituent unit;
dissolving a plurality of photoresists in the casting solvent;
wetting the plurality of photoresists; and
grafting the plurality of polymer brushes to a silicon nitride surface.

2. The method of claim 1, further comprising:
neutralizing a plurality of amines with an acidic functional group in the first constituent unit of the plurality of polymer brushes.

3. The method of claim 1, further comprising:
sterically hindering a plurality of amines using the plurality of polymer brushes by the first constituent unit of the plurality of polymer brushes which have a molecular weight between 5000 Daltons and 15000 Daltons.

4. The method of claim 1, wherein wetting the plurality of photoresists, comprises:
immersing the plurality of polymer brushes with the plurality of photoresists through the second constituent unit, wherein the second constituent unit is chemically connected to the first constituent unit.

5. The method of claim 2, wherein the acidic functional group in the first constituent unit of the plurality of polymer brushes, comprises at least one of:
a carboxylic acid functional group, and
a phenol functional group.

6. The method of claim 1, wherein grafting the plurality of polymer brushes to the silicon nitride surface, comprises:
chemically creating a silicon-oxygen bond.

7. The method of claim 1, further comprising:
spin coating a polymer used to derive the plurality of polymer brushes.

8. The method of claim 1, further comprising:
selectively removing ungrafted polymer using the casting solvent while maintaining the grafted plurality of polymer brushes to the silicon nitride surface.

9. A photoresist system comprising:
silicon nitride deposited as a layer above a wafer; and
a plurality of polymer brushes deposited above the silicon nitride layer, wherein each of the plurality of polymer brushes contains:
a plurality of amines dispersed throughout the silicon nitride layer,
an oxygen atom, and
a constituent unit; and
a plurality of photoresists deposited over the plurality of polymer brushes.

10. The photoresist system of claim 9, wherein the polymer brush comprises:
a 2-3 nm stack with one or more neutralizing functional groups; and
a 2-3 nm stack with one or more sterically imposing functional groups.

11. The photoresist system of claim 10, wherein the one or more neutralizing functional groups, comprises:
one or more phenol functional groups.

12. The photoresist system of claim 10, wherein the one or more sterically imposing functional groups, comprises:
polystyrene of a molecular weight between 5000 Daltons to 15000 Daltons.

13. The photoresist system of claim 9, wherein each polymer brush of derives from a polymer containing a hydroxyl group and the constituent unit.

14. The photoresist system of claim 9, wherein:
the constituent unit is chemically connected to the oxygen atom, wherein the oxygen atom chemically grafts to the silicon nitride; and
the constituent unit is connected by immersion to the plurality of photoresists, wherein the constituent unit is miscible with the plurality of photoresists.

15. A photoresist system comprising:
silicon nitride deposited as a layer above a wafer; and
a plurality of polymer brushes deposited above the silicon nitride layer, wherein each of the plurality of polymer brushes contains:
a plurality of amines dispersed throughout the silicon nitride layer,
an oxygen atom,
a first constituent unit, and
a second constituent unit; and
a plurality of photoresists deposited over the plurality of polymer brushes.

16. The photoresist system of claim 15, wherein the polymer brush comprises:
a 2-3 nm stack with one or more neutralizing functional groups; and
a 2-3 nm stack with one or more sterically imposing functional groups.

17. The photoresist system of claim 16, wherein the one or more neutralizing functional groups, comprises at least one of:
one or more carboxylic acid functional groups; and
one or more phenol functional groups.

18. The photoresist system of claim 16, wherein the one or more sterically imposing functional groups comprises:
polystyrene of a molecular weight between 5000 Daltons to 15000 Daltons.

19. The photoresist system of claim 15, further comprising:
the first constituent unit chemically connects to the oxygen atom, wherein the oxygen atom chemically grafts to the silicon nitride; and
the second constituent unit chemically connects to the first constituent unit, wherein the second constituent unit is miscible with the plurality of photoresists.

20. The photoresist system of claim 15, wherein the polymer brush derives from a polymer containing a hydroxyl group, the first constituent unit, and the second constituent unit.
